(19) United States
(12) Patent Application Publication
(10) Pub. No.: US 2014/0159149 A1
(43) Pub. Date: Jun. 12, 2014

(54) SHORT CHANNEL TRENCH MOSFETS

(71) Applicant: FORCE MOS TECHNOLOGY CO., LTD., New Taipei City (TW)

(72) Inventor: Fu-Yuan HSIEH, New Taipei City (TW)

(73) Assignee: Force Mos Technology Co., Ltd., New Taipei City (TW)

(21) Appl. No.: 13/711,857

(22) Filed: Dec. 12, 2012

(51) Int. Cl. H01L 29/78

(52) U.S. Cl. CPC H01L 29/7827
USPC 257/331

(57) ABSTRACT

A trench MOSFET with a short channel length is disclosed for reducing channel resistance, wherein at least one field relief region is formed underneath the body region in an epitaxial layer between every two adjacent gate trenches and self-aligned with a trenched source-body contact for prevention of drain/source punch-through issue.

### FIELD OF THE INVENTION

This invention relates generally to the cell structure and device configuration of power semiconductor devices. More particularly, this invention relates to a novel and improved cell structure and device configuration of a trench MOSFET (Metal Oxide Semiconductor Field Effect Transistor) with a short channel length.

### BACKGROUND OF THE INVENTION

FIG. 1 shows a conventional trench MOSFET 100 having a long channel length of prior art to prevent punch-through between N+ drain region and n+ source regions, wherein a trenched source-body contact 101 is penetrating through n+ source regions 102 and extending into a P body region 103 between two adjacent gate trenches 105 in an active area, wherein the n+ source regions 102 have a same doping concentration and a same junction depth at a same distance from a top surface of an N epitaxial layer 104 where the trench MOSFET 100 is formed. The gate trenches 105 are implemented to have a single gate structure comprising a single electrode 106 padded by a gate oxide layer 107, wherein the gate oxide layer 107 has a thickness along sidewalls equal to along bottom of the single electrode 106. When the trench MOSFET 100 is in the “on” state, the long channel length formed near the gate trenches 105 in the P body region 103 from the source regions 102 to the N+ drain region results in a high channel resistance.

Therefore, there is still a need in the art of the semiconductor power device, particularly for trench MOSFET design and fabrication, to provide a novel cell structure, device configuration that would resolve these difficulties and design limitations.

### SUMMARY OF THE INVENTION

The present invention provides a trench MOSFET with a short channel structure to reduce the channel resistance as discussed above, more important, without having punch-through problem for Rds (resistance between drain and source, the same herein after) reduction.

According to one aspect of the present invention, there is provided a trench MOSFET formed in an epitaxial layer of a first conductivity type onto a substrate of the first conductivity type, comprising: a short channel structure having a channel length less than 0.5 um without having punch-through problem, further comprising: a plurality of gate trenches starting from a top surface of the epitaxial layer and extending downward in an active area, the gate trenches being filled with a gate electrode padded by a gate oxide layer; a body region of a second conductivity type formed in an upper portion of the epitaxial layer between every two adjacent of the gate trenches; a source region of the first conductivity type encompassed in the body region, at least one field relief region of the second conductivity type formed underneath each the body region and in the epitaxial layer between every two adjacent of the gate trenches. The implement of the at least one field relief region allows the short channel formation with the channel length less than 0.5 um without having punch-through problem.

According to another aspect, the present invention further comprising: a trenched source-body contact filled with a contact metal plug, extending through the source region and extending into the body region between every two adjacent of the gate trenches in the active area; a body contact doped region of the second conductivity type within the body region, surrounding at least a bottom of the trenched source-body contact below the source region, wherein the field relief region is self-aligned to the trenched source-body contact because it is formed by implanting dopant of the field relief region through the trenched source-body contact during manufacturing process. According to some preferred embodiments, the source region has a same junction depth and a same doping concentration between sidewalls of the trenched source-body contact and the short channel at a same distance from a top surface of the epitaxial layer. According to other preferred embodiments, the source region has a higher doping concentration and a greater junction depth along the sidewalls of the trenched source-body contact than along the short channel at a same distance from the top surface of the epitaxial layer. This non-uniform distribution of the source region in lateral direction helps to enhance avalanche capability and save a source mask in manufacturing process, which is disclosed in U.S. Pat. No. 7,816,720 and U.S. Pat. No. 8,058,685, which have the same inventor as the present invention.

According to another aspect, the gate electrode filled in each of the gate trenches is a single gate electrode, and the gate oxide layer padded the single gate electrode has a thickness along bottoms greater than along sidewalls of the gate trenches. In some other preferred embodiments, the gate oxide also can be implemented to have a thickness along bottoms equal to or thinner than along sidewalls of the gate trenches.

According to another aspect, the gate electrode filled in each of the gate trenches is a single gate electrode, and the gate oxide layer padded the single gate electrode has a thickness along a lower portion of the gate trenches below the body region greater than along an upper portion of the gate trenches.

According to another aspect, the gate electrode filled in each of the gate trenches is disposed above a shielded electrode which is insulated from the epitaxial layer by a shielded electrode insulation layer having a greater thickness on sidewalls of the gate trenches than the gate oxide layer padded the gate electrode, wherein the gate electrode and the shielded electrode are insulated from each other by an inter-electrode insulation layer.

According to another aspect, the present invention can be implemented to have multiple field relief regions of the second conductivity type underneath the body region. For example, the present invention further comprises two field relief regions underneath the body region, wherein one of the two field relief regions is disposed above the other.

According to another aspect, the gate trenches in the active area are further extending to a termination area of the present invention for formation of multiple trenched floating gates which have a same filling-in structure as the gate trenches in the active area except for having a floating voltage, wherein the multiple trenched floating gates in the termination area are spaced apart from each other by the body region without encompassing the source region.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a trench MOSFET of a prior art.

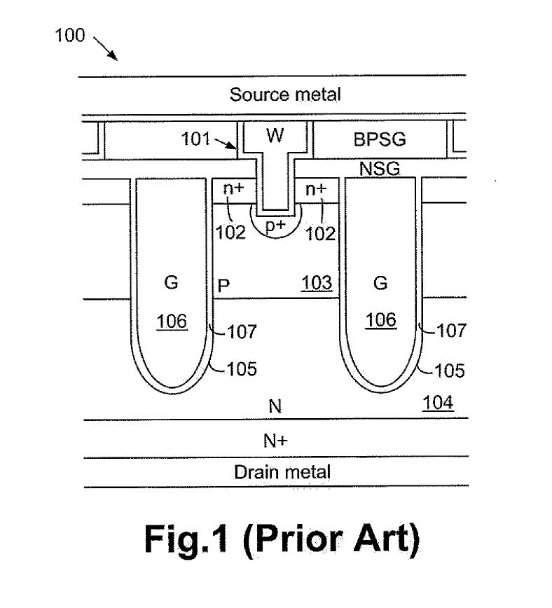

FIG. 2 is a cross-sectional view of a preferred embodiment according to the present invention.

FIG. 3 is a cross-sectional view of another preferred embodiment according to the present invention.

FIG. 4 is a cross-sectional view of another preferred embodiment according to the present invention.

FIG. 5 is a cross-sectional view of another preferred embodiment according to the present invention.

FIG. 6 is a cross-sectional view of another preferred embodiment according to the present invention.

FIG. 7 is a cross-sectional view of another preferred embodiment according to the present invention.

FIG. 8 is a cross-sectional view of another preferred embodiment according to the present invention.

FIG. 9 is a cross-sectional view of another preferred embodiment according to the present invention.

### DETAILED DESCRIPTION OF THE EMBODIMENTS

In the following Detailed Description, reference is made to the accompanying drawings, .which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

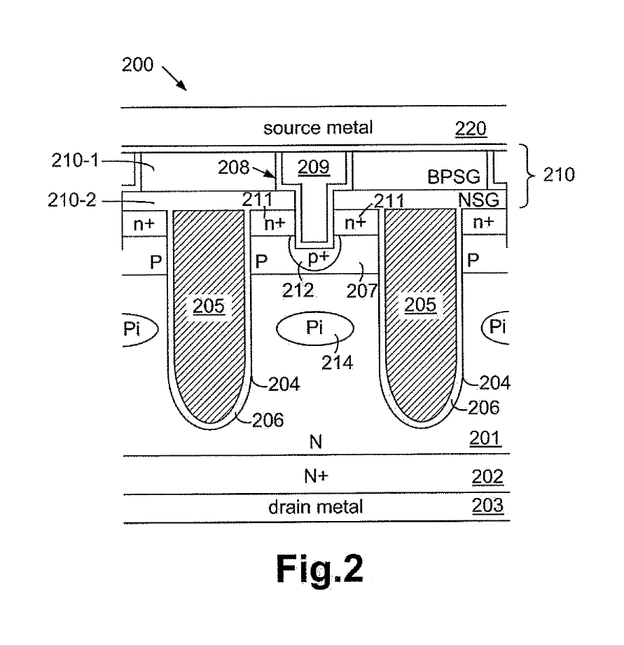

Please refer to FIG. 2 for a preferred active area of this invention wherein an N-channel trench MOSFET 200 is formed in an N epitaxial layer 201 onto an N+ substrate 202 coated with a back metal of Ti/Ni/Ag on a rear side as a drain metal 203. A plurality of gate trenches 204 are formed starting from a top surface of the N epitaxial layer 201 and extending downward into the N epitaxial layer 201, each of the gate trenches 204 is formed having a single gate electrode 205 padded by a gate oxide layer 206 which has a thickness along bottoms equal to or thinner than along sidewalls of the gate trenches 204. The single electrode 205 can be implemented by using doped poly-silicon layer. A P body region 207 encompassing an n+ source region 211 is formed in an upper portion of the N epitaxial layer 201 between every two adjacent of the gate trenches 204, wherein the P body region 207 has a shallower junction depth compared to the prior art for formation of the short channel structure, and the n+ source region 211 has a same doping concentration and a same junction depth at a same distance from the top surface of the N epitaxial layer 201 between sidewalls of a trenched source-body contact 208 and the short channel, wherein the trenched source-body contact 208 filled with a contact metal plug 209 is penetrating through a contact interlayer 210 comprising a BPSG layer 210-1 onto an NSG layer 210-2, the n+ source region 211 and further extending into the P body region 207 between every two adjacent of the gate trenches 204 to connect each the P body region 207 and each the n+ source region 211 to a source metal 220, wherein the contact metal plug 209 is tungsten metal layer padded by a barrier metal layer of Ti/TiN or Co/TiN or Ta/TiN. Underneath the trenched source-body contact 208, a p+ body contact doped region 212 is formed within the P body region 207 and surrounding at least bottom of the trenched source-body contact 208 to reduce the contact resistance between the P body region 207 and the contact metal plug 209. For example, the p+ body contact doped region 212 can be implemented surrounding bottom and sidewalls of the trenched source-body contact 208 below the n+ source region 211. Specially, a single implanted p island (Pi, as illustrated in FIG. 2) 214 is formed through openings of the trenched source-body contact 208 during manufacturing process, in the N epitaxial layer 201 underneath the P body region 207 and between every two adjacent of the gate trenches 204 to act as a field relief region which is self-aligned with the trenched source-body contact 208 for prevention of drain/source punch-through issue. When the trench MOSFET 200 is in the “on” state, the short channels will be formed near the gate trenches 204 in each the P body region 207 in the active area from the n+ source regions 211 to a drain region, therefore the channel resistance is reduced.

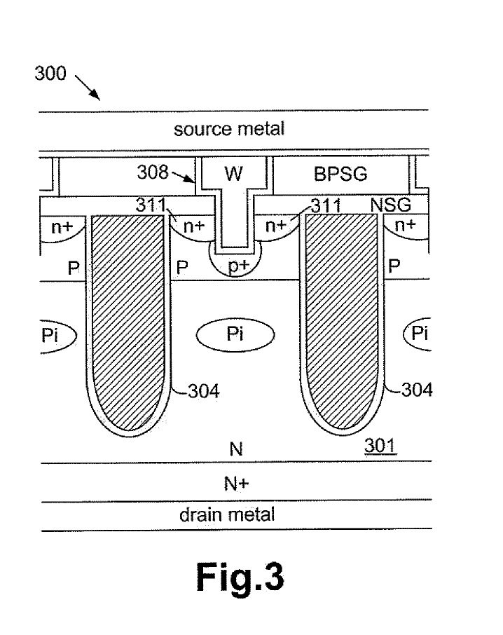

FIG. 3 shows a cross-sectional view of another trench MOSFET 300 according to the present invention. The trench MOSFET 300 has a similar active structure to the trench MOSFET 200 in FIG. 2 except that, in FIG. 3, each the n+ source region 311 has a higher doping concentration and a greater junction depth along sidewalls of the trenched source-body contact 308 than along the adjacent short channel near the gate trenches 304 at a same distance from the top surface of the N epitaxial layer 301, and each the n+ source region 311 has a doping profile of Gaussian-distribution along the top surface of the N epitaxial layer 301 from the sidewalls of the trenched source-body contact 308 to the adjacent short channel, as disclosed in U.S. Pat. No. 7,816,720 and U.S. Pat. No. 8,058,685 of the same inventor and assignee, therefore the source mask is saved and avalanche capability of the trench MOSFET 300 is enhanced.

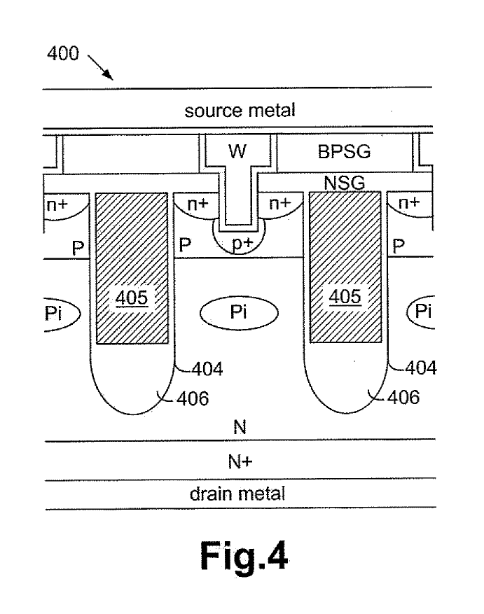

FIG. 4 shows a cross-sectional view of another trench MOSFET 400 according to the present invention. The trench MOSFET 400 has a similar active structure to the trench MOSFET 300 in FIG. 3 except that, in FIG. 4, the gate oxide layer 406 padded each the single gate electrode 405 has a greater thickness along bottom than along sidewalls of the gate trenches 404.

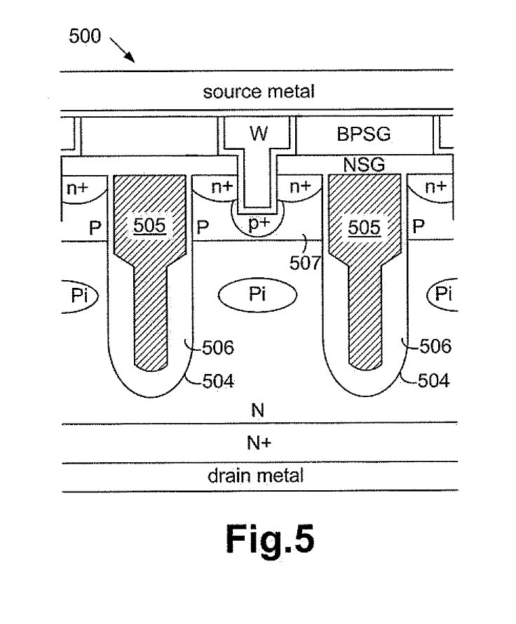

FIG. 5 shows a cross-sectional view of another trench MOSFET 500 according to the present invention. The trench MOSFET 500 has a similar active structure to the trench MOSFET 300 in FIG. 3 except that, in FIG. 5, the gate oxide layer 506 padded each the single gate electrode 505 has a greater thickness along bottom and a lower portion of the gate trenches 504 below the P body regions 507 than along an upper portion of the gate trenches 504.

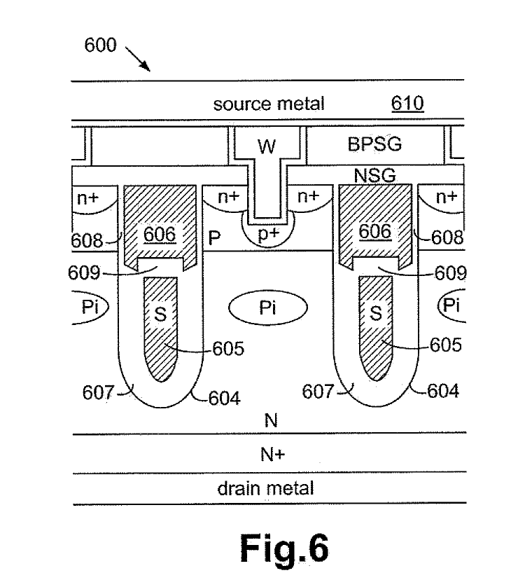

FIG. 6 shows a cross-sectional view of another trench MOSFET 600 according to the present invention. The trench MOSFET 600 has a similar active structure to the trench MOSFET 300 in FIG. 3 except that, in FIG. 6, the gate trenches 604 are refilled with dual electrodes structure comprising a shielded electrode (S, as illustrated in FIG. 6) 605 in a lower portion and a gate electrode (G, as illustrated in FIG. 6) 606 in an upper portion of each of the gate trenches 604, wherein sidewalls and bottom of the shielded electrode 605 are surrounded by a shielded electrode insulation layer 607, sidewalls of the gate electrode 606 are surrounded by a gate oxide layer 608, wherein the shielded electrode 605 and the gate electrode 606 are insulated from each other by an inter-electrode insulation layer 609. Meanwhile, the shielded electrode 605 is further connected to a source metal 610.

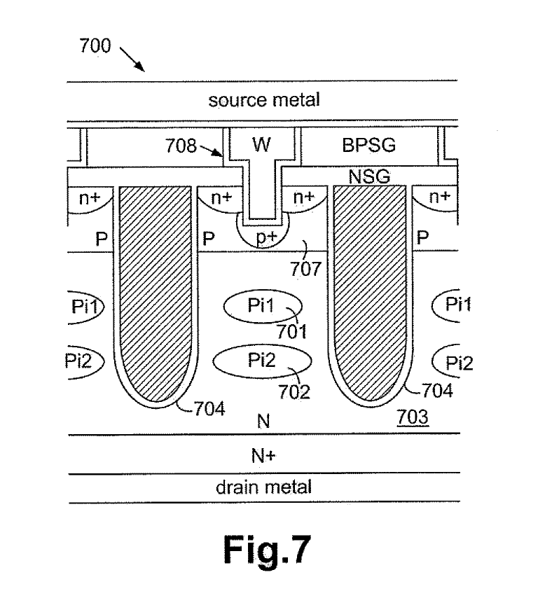

FIG. 7 shows a cross-sectional view of another trench MOSFET 700 according to the present invention. The trench MOSFET 700 has a similar active structure to the trench MOSFET 300 in FIG. 3 except that, in FIG. 7, two p islands (a first P island “Pi1” and a second P island “Pi2”, as illustrated in FIG. 7) respectively serving as field relief regions 701 and 702 are formed one above another and underneath the P body region 707 in the N epitaxial layer 703 between every two adjacent of the gate trenches 704 and self-aligned with the trenched source-body contact 708 for further prevention of drain/source punch-through issue.

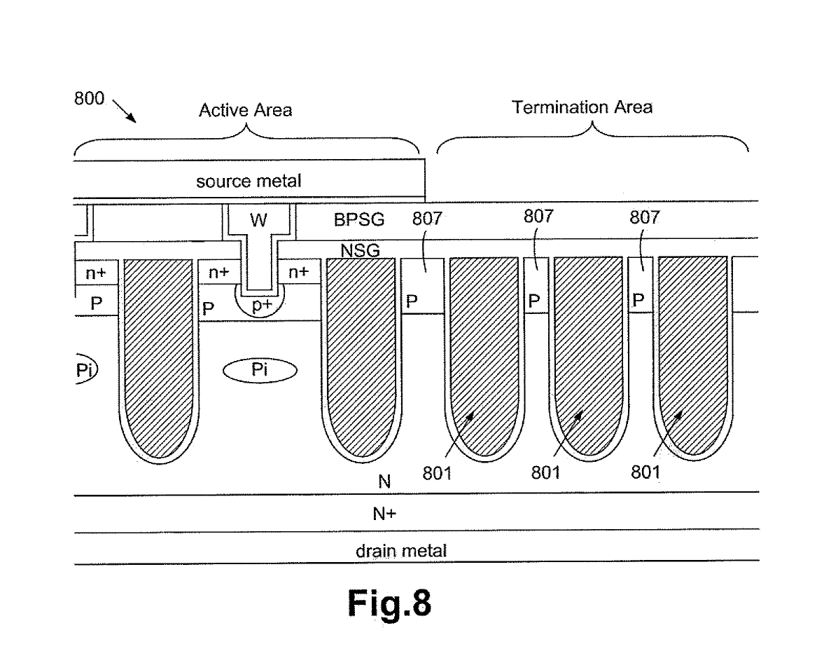

FIG. 8 shows a cross-sectional view of another trench MOSFET 800 according to the present invention. The trench MOSFET 800 has a similar active structure to the trench MOSFET 200 in FIG. 2 except that, in FIG. 8, the trench MOSFET 800 further comprises a termination area including multiple trenched floating gates 801 spaced apart from each other by the P body region 807 without encompassing source region and without having field relief region underneath the P body region 807, as disclosed in U.S. Pat. No. 7,989,887 of the same inventor and the same assignee, wherein the trenched floating gates 801 have floating voltage.

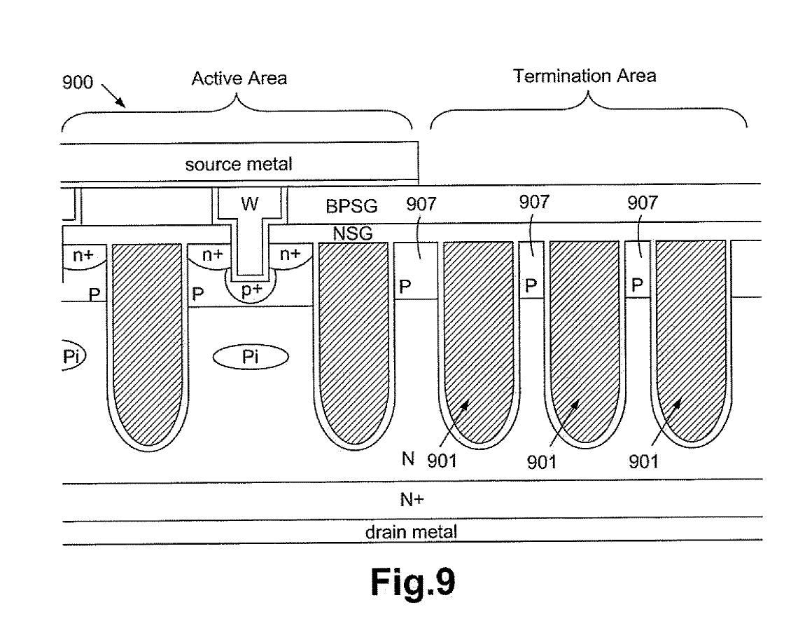

FIG. 9 shows a cross-sectional view of another trench MOSFET 900 according to the present invention. The trench MOSFET 900 has a similar active structure to the trench MOSFET 300 in FIG. 3 except that, in FIG. 9, the trench MOSFET 900 further comprises a termination area including multiple trenched floating gates 901 spaced apart from each other by the P body region 907, wherein the trenched floating gates 901 have floating voltage.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET with a short channel formed in an epitaxial layer of a first conductivity type onto a substrate of said first conductivity type, comprising:
a plurality of gate trenches starting from a top surface of said epitaxial layer and extending downward in an active area, said gate trenches being filled with a gate electrode padded by a gate oxide layer;
a body region of a second conductivity type formed in an upper portion of said epitaxial layer between every two adjacent of said gate trenches;
a source region of said first conductivity type encompassed in said body region;
at least one field relief region of said second conductivity type formed underneath each said body region and in said epitaxial layer between every two adjacent of said gate trenches.

2. The trench MOSFET of claim 1 wherein said short channel has a channel length less than 0.5 um.

3. The trench MOSFET of claim 1 further comprising:
a trenched source-body contact filled with a contact metal plug, penetrating through said source region and extending into said body region between every two adjacent of said gate trenches in said active area;
a body contact doped region of said second conductivity type within said body region, surrounding at least a bottom of said trenched source-body contact below said source region.

4. The trench MOSFET of claim 3, wherein said field relief region is self-aligned with said trenched source-body contact.

5. The trench MOSFET of claim 3, wherein said source region has a same junction depth and a same doping concentration between sidewalls of said trenched source-body contact and adjacent said short channel at a same distance from a top surface of said epitaxial layer.

6. The trench MOSFET of claim 3, wherein said source region has a higher doping concentration and a greater junction depth along sidewalls of said trenched source-body contact than along adjacent said short channel at a same distance from a top surface of said epitaxial layer.

7. The trench MOSFET of claim 1, wherein said gate electrode filled in each of the gate trenches is a single gate electrode padded by said gate oxide layer.

8. The trench MOSFET of claim 7, wherein said gate oxide layer padded said single gate electrode has a greater thickness along bottoms than along sidewalls of said gate trenches.

9. The trench MOSFET of claim 7, wherein said gate oxide layer padded said single gate electrode has a thickness along bottoms equal to or thinner than along sidewalls of said gate trenches.

10. The trench MOSFET of claim 7, wherein said gate oxide layer padded said single gate electrode has a greater thickness along bottom and a lower portion of said gate trenches below said body region than along an upper portion of said gate trenches.

11. The trench MOSFET of claim 1, wherein said gate electrode filled in each of said gate trenches is disposed above a shielded electrode which is insulated from said epitaxial layer by a shielded electrode insulation layer having a greater thickness on sidewalls of said gate trenches than said gate oxide layer, wherein said gate electrode and said shielded electrode are insulated from each other by an inter-electrode insulation layer.

12. The trench MOSFET of claim 1 further comprising two field relief regions of said second conductivity type underneath said body region, wherein said two field relief regions are formed one above another.

13. The trench MOSFET of claim 1 further comprising multiple field relief regions of said second conductivity type underneath said body region, wherein said multiple field relief regions are formed one above another.

14. The trench MOSFET of claim 1 further comprising a termination area including multiple trenched floating gates having a floating voltage, wherein said multiple trenched floating gates in the termination area are spaced apart from each other by said body region without encompassing said source region.
